(19) United States
(12) Patent Application Publication
(10) Pub. No.: US 2024/0321837 A1
(43) Pub. Date: Sep. 26, 2024

(54) DISPLAY APPARATUS

(71) Applicant: Samsung Display Co., Ltd., Yongin-si (KR)

(72) Inventor: Heemin Park, Yongin-si (KR)

(73) Assignee: Samsung Display Co., Ltd., Yongin-si (KR)

(21) Appl. No.: 18/613,867

(22) Filed: Mar. 22, 2024

(30) Foreign Application Priority Data
Mar. 24, 2023 (KR) 10-2023-0039254
Jun. 26, 2023 (KR) 10-2023-0082205

(51) Int. Cl. H01L 25/075; H01L 33/42

(52) U.S. Cl. CPC H01L 25/0753; H01L 33/42; H01L 2933/0016

(57) ABSTRACT

A display apparatus includes a first sub-pixel electrode disposed on a substrate, a conductive bank layer including a first opening overlapping the first sub-pixel electrode and including a first conductive layer and a second conductive layer disposed on the first conductive layer, a first intermediate layer overlapping the first sub-pixel electrode through the first opening of the conductive bank layer, and a first opposite electrode overlapping the first intermediate layer through the first opening of the conductive bank layer, the second conductive layer includes a first tip that protrudes towards the first opening from a first point, at which a side surface of the first conductive layer meets a bottom surface of the second conductive layer, and the first tip includes an upward curved portion with respect to a thickness direction of the substrate.

### CROSS-REFERENCE TO RELATED APPLICATIONS

This application claims priority to and benefits of Korean Patent Application Nos. 10-2023-0039254 under 35 U.S.C. § 119, filed on Mar. 24, 2023, and 10-2023-0082205 under 35 U.S.C. § 119, filed on Jun. 26, 2023, in the Korean Intellectual Property Office, the entire contents of which are incorporated herein by reference.

### BACKGROUND

### 1. Technical Field

One or more embodiments relate to a structure of a display apparatus and a method of manufacturing the display apparatus.

### 2. Description of the Related Art

Display apparatuses visually display data. Such display apparatuses may each include a substrate including a display area and a peripheral area. In the display area, scan lines and data lines are insulated from each other, and pixels may be included. Also, in the display area, thin-film transistors and sub-pixel electrodes electrically connected to the thin-film transistors may be included respectively corresponding to the pixels. Also, an opposite electrode commonly included in the pixels may be included in the display area. In the peripheral area, various wires, a scan driver, a data driver, a controller, a pad portion, etc. may be included to transmit electrical signals to the display area.

Such display apparatuses have been used in various fields. Accordingly, various designs have been made to improve the quality of display apparatuses.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus, in which resolution is improved and high-quality images may be implemented. However, this is an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus may include a first sub-pixel electrode disposed on a substrate; a conductive bank layer including a first opening overlapping the first sub-pixel electrode and including a first conductive layer and a second conductive layer disposed on the first conductive layer; a first intermediate layer overlapping the first sub-pixel electrode through the first opening of the conductive bank layer; and a first opposite electrode overlapping the first intermediate layer through the first opening of the conductive bank layer, wherein the second conductive layer may include a first tip that protrudes towards the first opening from a first point, at which a side surface of the first conductive layer meets a bottom surface of the second conductive layer, and the first tip may include an upward curved portion with respect to a thickness direction of the substrate.

The display apparatus may further include a first dummy intermediate layer disposed on the conductive bank layer, the first dummy intermediate layer and the first intermediate layer including a same material, and a first dummy opposite electrode disposed on the first dummy intermediate layer, the first dummy opposite electrode and the first opposite electrode including a same material, wherein the first intermediate layer may be spaced apart from the first dummy intermediate layer, and the first opposite electrode may be spaced apart from the first dummy opposite electrode.

The display apparatus may further include an auxiliary layer disposed between the first dummy intermediate layer and the first dummy opposite electrode.

The display apparatus may further include a dummy auxiliary layer disposed between the first intermediate layer and the first opposite electrode through the first opening of the conductive bank layer, the dummy auxiliary layer and the auxiliary layer including a same material, wherein the auxiliary layer may be spaced apart from the dummy auxiliary layer.

The auxiliary layer and the dummy auxiliary layer may include different materials from the first opposite electrode.

A thickness of each of the auxiliary layer and the dummy auxiliary layer may be between about 300 Å and about 1000 Å.

The auxiliary layer may include a transparent electrode.

The auxiliary layer may include transparent conductive oxide (TCO).

The auxiliary layer may include a semi-transmissive electrode, and the auxiliary layer may include a transparent conductive layer and a semi-transmissive metal layer.

The first opposite electrode and the first dummy opposite electrode may include a reflection electrode.

The first opposite electrode and the first dummy opposite electrode may each include at least one selected from the group consisting of ytterbium (Yb), copper (Cu), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), and molybdenum (Mo).

The first opposite electrode and the first dummy opposite electrode may include a transparent conductive layer.

The first opposite electrode and the first dummy opposite electrode may include TCO.

The first tip may include a surface that is convex and another surface that is concave, and the surface that is convex may face the substrate.

An outer portion of the first opposite electrode may directly contact the side surface of the first conductive layer which faces the first opening of the conductive bank layer.

According to one or more embodiments, a method of manufacturing a display apparatus may include forming a first sub-pixel electrode on a substrate; forming a conductive bank layer including a first opening overlapping the first sub-pixel electrode and including a first conductive layer and a second conductive layer disposed on the first conductive layer; forming a first intermediate layer to overlap the first sub-pixel electrode through the first opening of the conductive bank layer; and forming a first opposite electrode to overlap the first intermediate layer through the first opening of the conductive bank layer, wherein the second conductive layer may include a first tip that protrudes towards the first opening from a first point, at which a side surface of the first conductive layer meets a bottom surface of the second conductive layer, and the first tip may include an upward curved portion with respect to a thickness direction of the substrate.

The method may further include forming a first dummy intermediate layer disposed on the conductive bank layer, the first dummy intermediate layer and the first intermediate layer including a same material; and forming a first dummy opposite electrode disposed on the first dummy intermediate layer, the first dummy opposite electrode and the first opposite electrode including a same material, wherein the first intermediate layer and the first dummy intermediate layer may be formed through a same process and spaced apart from each other, and the first opposite electrode and the first dummy opposite electrode may be formed through a same process and spaced apart from each other.

The method may further include forming an auxiliary layer to be disposed between the first dummy intermediate layer and the first dummy opposite electrode after the forming of the first dummy intermediate layer and before the forming of the first dummy opposite electrode. The first tip may be curved upwards by a tensile stress of the auxiliary layer.

The auxiliary layer may include a transparent electrode, and the first opposite electrode may include a semi-transmissive electrode.

The auxiliary layer may be formed through sputtering, and the first opposite electrode and the first dummy opposite electrode may be formed through evaporation.

The forming of the auxiliary layer may include performing sputtering under a pressure ranging from about 7 mTorr to about 15 mTorr.

The auxiliary layer may be formed through sputtering under a first pressure, and the first opposite electrode and the first dummy opposite electrode may be formed through sputtering under a second pressure that is lower than the first pressure.

The first pressure may be between about 7 mTorr and about 15 mTorr, and the second pressure may be between about 3 mTorr and about 7 mTorr.

The first opposite electrode and the first dummy opposite electrode may include a transparent electrode.

The first opposite electrode and the first dummy opposite electrode may be formed through sputtering under a pressure ranging from about 7 mTorr to about 15 mTorr.

The first tip may be curved upwards by a tensile stress of the first dummy opposite electrode.

### BRIEF DESCRIPTION OF THE DRAWINGS

The above and other aspects, features, and advantages of embodiments of the disclosure will be more apparent from the following description taken in conjunction with the accompanying drawings, in which:

FIGS. 1A and 1B are schematic perspective views of a display apparatus according to an embodiment;

FIGS. 2A and 2B are schematic equivalent circuit diagrams of a light-emitting diode corresponding to any one of sub-pixels of a display apparatus and a sub-pixel circuit electrically connected to the light-emitting diode, according to an embodiment;

FIGS. 3A to 3L are schematic cross-sectional views of states of a display apparatus according to manufacturing processes, according to an embodiment;

FIG. 3M is a schematic cross-sectional view of a stack structure of a light-emitting diode, according to an embodiment;

FIG. 4 is a schematic cross-sectional view of a display apparatus according to an embodiment; and

FIG. 5 is a schematic cross-sectional view of a display apparatus according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, various embodiments will be shown in the drawings and described in detail in the written description. The attached drawings for illustrating embodiments are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

One or more embodiments will be described more fully with reference to the accompanying drawings, like reference numerals in the drawings denote like elements, and repeated descriptions thereof may not be provided.

It will be understood that although the terms “first,” “second,” etc. may be used herein to describe various components, these components should not be limited by these terms. These components are only used to distinguish one component from another. For example, a first element may be referred to as a second element, and similarly, a second element may be referred to as a first element without departing from the scope of the disclosure.

As used herein, the singular forms “a,” “an,” and “the” are intended to include the plural forms as well, unless the context clearly indicates otherwise.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when a layer, region, or element is referred to as being “formed on” another layer, region, or element, it can be directly or indirectly formed on the other layer, region, or element. For example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

When an embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it can be directly or indirectly connected to the other layer, region, or component. For example, when a layer, region, or component is referred to as being electrically connected to another layer, region, or component, it can be directly or indirectly electrically connected to the other layer, region, or component.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

In the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

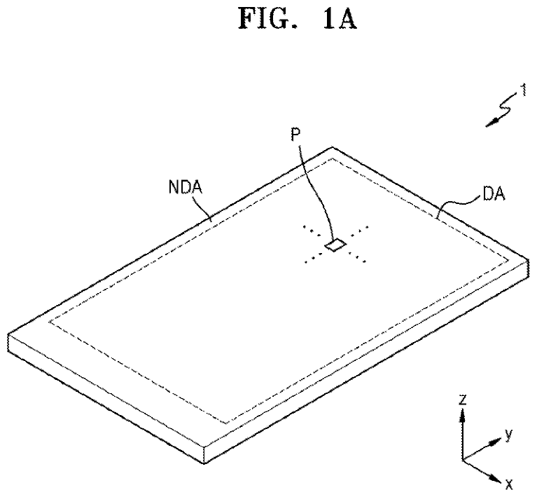

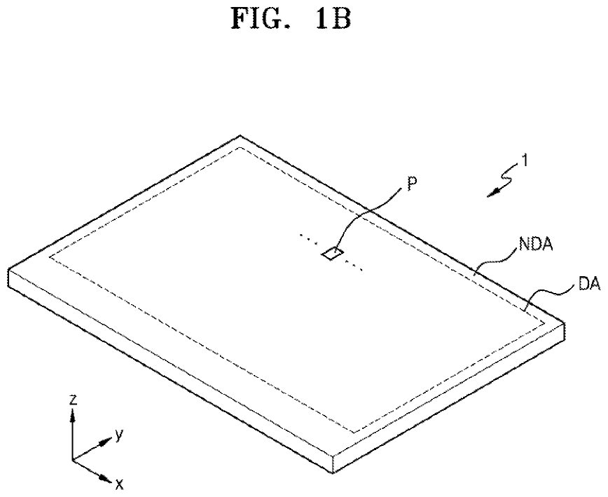

FIGS. 1A and 1B each are a schematic perspective view of a display apparatus according to an embodiment.

Referring to FIGS. 1A and 1B, a display apparatus 1 may include a display area DA and a non-display area NDA outside the display area DA. In the display area DA, images may be displayed through sub-pixels P arranged (or disposed) in the display area DA. The non-display area NDA may be a non-display area that is located or disposed outside of the display area DA and where no images are displayed, and may entirely surround or may be adjacent to the display area DA. In the non-display area NDA, drivers or the like that provide electrical signals or power to the display area DA may be arranged. In the non-display area NDA, a pad that may be electrically connected to an electronic component or a printed circuit board may be arranged.

In an embodiment, FIG. 1A shows a polygon (for example, a rectangle) in which the length of the display area DA in an x direction is less than that in a y direction, but in an embodiment, FIG. 1B may show a polygon (for example, a rectangle) in which the length of the display area DA in the y direction is less than that in the x direction. FIGS. 1A and 1B show that the shape of the display area DA is substantially a rectangle, but one or more embodiments are not limited thereto. In an embodiment, the display area DA may have various shapes, such as an n-sided polygon (where, N is a natural number greater than or equal to 3), a circle, or an oval. FIGS. 1A and 1B show that a corner portion of the display area DA may include a vertex where a straight line meets another straight line, but in an embodiment, the display area DA may have a polygonal shape with rounded corner portions.

Hereinafter, the display apparatus 1 is a smartphone for convenience of explanation, but is not limited thereto. The display apparatus 1 may be applied to various products, for example, a portable electric apparatus such as a mobile phone, a smartphone, a tablet Personal Computer (PC), a mobile communication terminal, a personal digital assistant, an e-book terminal, a portable multimedia player (PMP), a navigation device, or an ultra-mobile PC (UMPC), a television (TV), a laptop, a monitor, a billboard, an Internet of Things (IoT) device, and the like within the spirit and the scope of the disclosure. Also, in an embodiment, the display apparatus 1 may be used in a wearable device, such as a smartwatch, a watch phone, an eyewear display, or a head-mounted display (HMD). Also, in an embodiment, the display apparatus 1 may be used as a display screen in an instrument cluster of a vehicle, a Center Information Display (CID) mounted on a center fascia or a dashboard of a vehicle, a room mirror display replacing a side-view mirror of a vehicle, or a car headrest monitor provided for rear-seat entertainment.

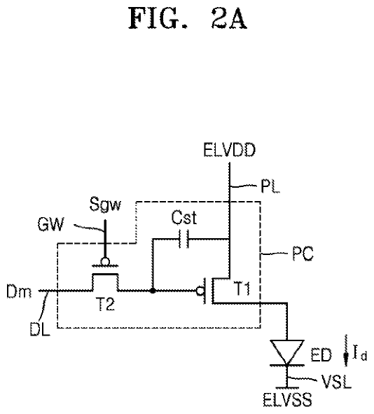

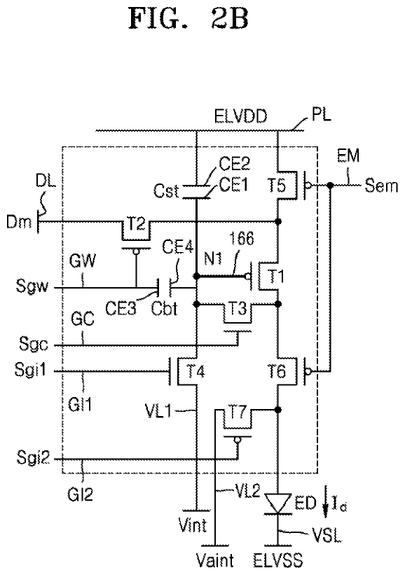

FIGS. 2A and 2B are schematic equivalent circuit diagrams of a light-emitting diode corresponding to any one of sub-pixels of a display apparatus and a sub-pixel circuit electrically connected to the light-emitting diode, according to an embodiment.

Referring to FIG. 2A, a light-emitting diode ED may be electrically connected to a sub-pixel circuit PC, and the sub-pixel circuit PC may include a first transistor T1, a second transistor T2, and a storage capacitor Cst. A sub-pixel electrode (for example, an anode) of the light-emitting diode ED may be electrically connected to the first transistor T1, and an opposite electrode (for example, a cathode) may be electrically connected to an auxiliary line VSL and receive a voltage corresponding to a common voltage ELVSS through the auxiliary line VSL.

The second transistor T2 may transmit, to the first transistor T1, a data signal Dm that is input through a data line DL, according to a scan signal Sgw that is input through a scan line GW.

The storage capacitor Cst may be connected to the second transistor T2 and a driving power line PL and may store a voltage corresponding to a difference between a voltage from the second transistor T2 and a driving voltage ELVDD provided to the driving power line PL.

The first transistor T1 may be connected to the driving power line PL and the storage capacitor Cst and may control a driving current I_{d} flowing in the light-emitting diode ED from the driving power line PL, according to the voltage stored in the storage capacitor Cst. The light-emitting diode ED may emit light having a given brightness according to the driving current I_{d}.

FIG. 2A shows that the sub-pixel circuit PC may include two transistors and one storage capacitor, but one or more embodiments are not limited thereto.

FIG. 2B is a schematic equivalent circuit diagram of a light-emitting diode corresponding to any one of sub-pixels of a display apparatus and a sub-pixel circuit electrically connected to the light-emitting diode, according to an embodiment.

Referring to FIG. 2B, the sub-pixel circuit PC may include seven transistors and two capacitors.

The sub-pixel circuit PC may include a first transistor T1 to a seventh transistor T7, a storage capacitor Cst, and a boost capacitor Cbt. In an embodiment, the sub-pixel circuit PC may not include the boost capacitor Cbt. A sub-pixel electrode (for example, an anode) of the light-emitting diode ED may be electrically connected to the first transistor T1 via the sixth transistor T6, and an opposite electrode (for example, a cathode) may be electrically connected to the auxiliary line VSL and receive a voltage corresponding to the common voltage ELVSS through the auxiliary line VSL.

Some or a number of the first transistor T1 to the seventh transistor T7 may each be a n-channel MOSFET (NMOS), and the others thereof may each be a p-channel MOSFET (PMOS). In an embodiment, as shown in FIG. 2B, the third transistor T3 and the fourth transistor T4 may each be an NMOS, and the others thereof may each be a PMOS. For example, the third transistor T3 and the fourth transistor T4 may each be an NMOS including an oxide semiconductor material, and the others may each be a PMOS including a silicon semiconductor material. In an embodiment, the third transistor T3, the fourth transistor T4, and the seventh transistor T7 may each be an NMOS, and the others may each be a PMOS.

The first transistor T1 to the seventh transistor T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and the data line DL. The sub-pixel circuit PC may be electrically connected to voltage lines, for example, the driving power line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving power line PL through the fifth transistor T5, and a second electrode of the first transistor T1 may be electrically connected to a first electrode (for example, an anode) of the light-emitting diode ED through the sixth transistor T6. One of the first electrode and the second electrode of the first transistor T1 may be a source electrode, and the other thereof may be a drain electrode. The first transistor T1 may provide a driving current I_{d} to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, a second electrode of the second transistor T2 may be connected to the first electrode of the first transistor T1 and electrically connected to the driving power line PL through the fifth transistor T5. One of the first electrode and the second electrode of the second transistor T2 may be a source electrode, and the other thereof may be a drain electrode. The second transistor T2 may be turned on in response to a scan signal Sgw transmitted through the scan line GW and perform a switching operation whereby a data signal Dm transmitted through the data line DL is transmitted to the first electrode of the first transistor T1.

The third transistor T3 may be a compensation transistor to compensate for a threshold voltage of the first transistor T1. A third gate electrode of the third transistor T3 is connected to the compensation gate line GC. A first electrode of the third transistor T3 is connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 is connected to the second electrode of the first transistor T1 and electrically connected to the first electrode (for example, the anode) of the light-emitting diode ED through the sixth transistor T6. One of the first electrode and the second electrode of the third transistor T3 may be a source electrode, and the other thereof may be a drain electrode.

The third transistor T3 is turned on in response to a compensation signal Sgc transmitted through the compensation gate line GC and electrically connects the second electrode (for example, a drain electrode) and the first gate electrode of the first transistor T1, thus diode-connecting the first transistor T1.

The fourth transistor T4 may be a first initialization transistor to initialize the first gate electrode of the first transistor T1. A fourth gate electrode of the fourth transistor T4 is connected to the first initialization gate line GI1. A first electrode of the fourth transistor T4 is connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other thereof may be a drain electrode. The fourth transistor T4 may be turned on in response to a first initialization signal Sgi1 transmitted through the first initialization gate line GI1 and transmit a first initialization voltage Vint to the first gate electrode of the first transistor T1, thus performing an initialization operation whereby a voltage of the first gate electrode of the first transistor T1 is initialized.

The fifth transistor T5 may be an operation control transistor. A fifth gate electrode of the fifth transistor T5 is connected to the emission control line EM, a first electrode of the fifth transistor T5 is connected to the driving power line PL, and a second electrode of the fifth transistor T5 is connected to the first electrode of the first transistor T1 and the second electrode of the second transistor T2. One of the first electrode and the second electrode of the fifth transistor T5 may be a source electrode, and the other thereof may be a drain electrode.

The sixth transistor T6 may be an emission control transistor. A sixth gate electrode of the sixth transistor T6 is connected to the emission control line EM, a first electrode of the sixth transistor T6 is connected to the second electrode of the first transistor T1 and the second electrode of the third transistor T3, and a second electrode of the sixth transistor t6 is electrically connected to a second electrode of the seventh transistor T7 and the first electrode (for example, the anode) of the light-emitting diode ED. One of the first electrode and the second electrode of the sixth transistor T6 may be a source electrode, and the other thereof may be a drain electrode.

The fifth transistor T5 and the sixth transistor T6 may be simultaneously turned on in response to an emission control signal Sem transmitted through the emission control line EM and transmit the driving voltage ELVDD to the light-emitting diode ED so that the driving current I_{d} flows in the light-emitting diode ED.

The seventh transistor T7 may be a second initialization transistor to initialize the first electrode (for example, the anode) of the light-emitting diode ED. A seventh gate electrode of the seventh transistor T7 is connected to the second initialization gate line GI2. A first electrode of the seventh transistor T7 is connected to the second initialization voltage line VL2. The second electrode of the seventh transistor T7 is connected to the second electrode of the sixth transistor T6 and the first electrode (for example, the anode) of the light-emitting diode ED. The seventh transistor T7 may be turned on in response to a second initialization signal Sgi2 transmitted through the second initialization gate line GI2 and transmit a second initialization voltage Vaint to the first electrode (for example, the anode) of the light-emitting diode ED, thus initializing the first electrode of the light-emitting diode ED.

In an embodiment, the second initialization gate line GI2 may be a next scan line. For example, the second initialization gate line GI2 connected to the seventh transistor T7 of the sub-pixel circuit PC arranged in an i^{th} row (where, i is a natural number) may correspond to a scan line of the sub-pixel circuit PC arranged in an (i+1)^{th} row. In other embodiments, the second initialization voltage line VL2 may be the emission control line EM. For example, the emission control line EM may be electrically connected to the fifth transistor T5 to the seventh transistor T7.

The storage capacitor Cst may include the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving power line PL. The storage capacitor Cst may store therein electric charges corresponding to a difference between the voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may increase a voltage of a first node NI in case that the scan signal Sgw provided to the scan line GW is turned off, and in case that the voltage of the first node NI increases, a black-gray scale may be clearly expressed.

The first node NI may be a region where the first gate electrode of the first transistor T1, the first electrode of the third transistor T3, the second electrode of the fourth transistor T4, and the fourth electrode CE4 of the boost capacitor Cbt are connected.

In an embodiment, FIG. 2B shows that the third transistor T3 and the fourth transistor T4 may each be an NMOS, and the first transistor T1, the second transistor T2, and the fifth transistor T5 to the seventh transistor T7 may each be a PMOS. The first transistor T1 directly affecting the brightness of the display apparatus for displaying images may include a semiconductor layer including polycrystalline silicon with high reliability, and thus, a high-resolution display apparatus may be realized.

FIG. 2B shows that some or a number of transistors are each an NMOS and the other transistors each are a PMOS, but one or more embodiments are not limited thereto. In an embodiment, various modifications may be made; for example, the sub-pixel circuit PC may include three transistors, and all of the transistors are NMOSs.

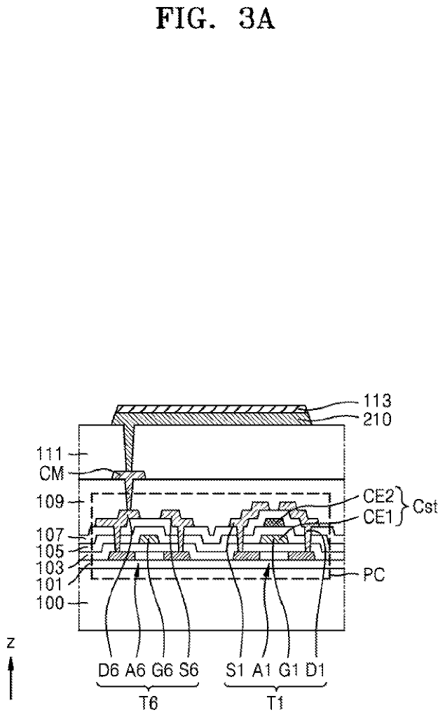

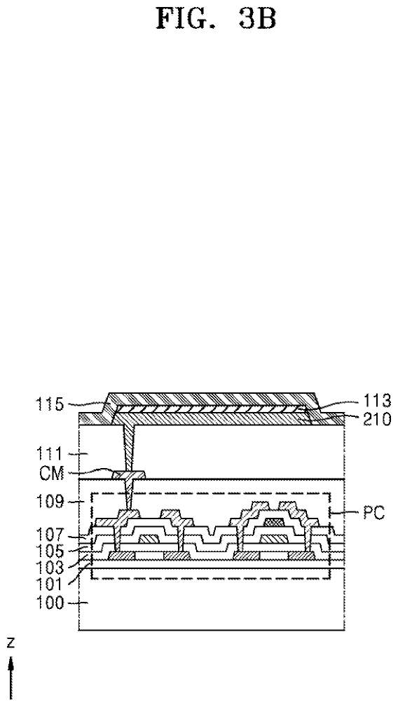

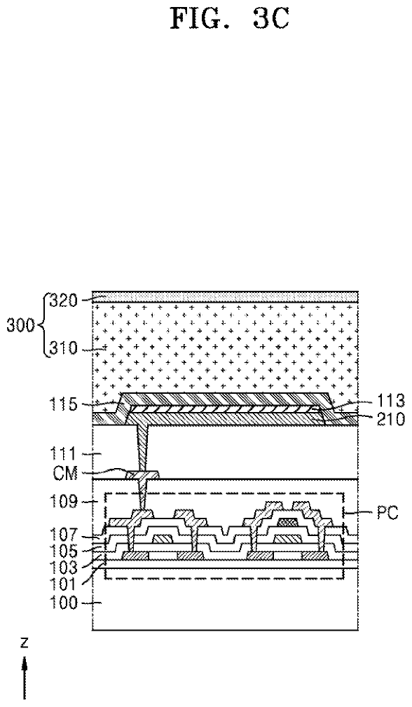

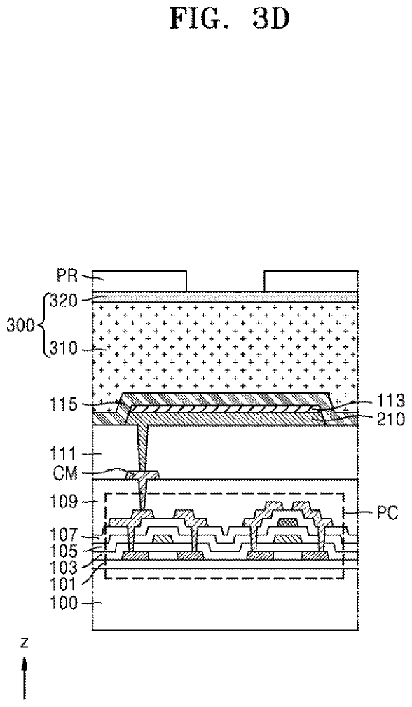

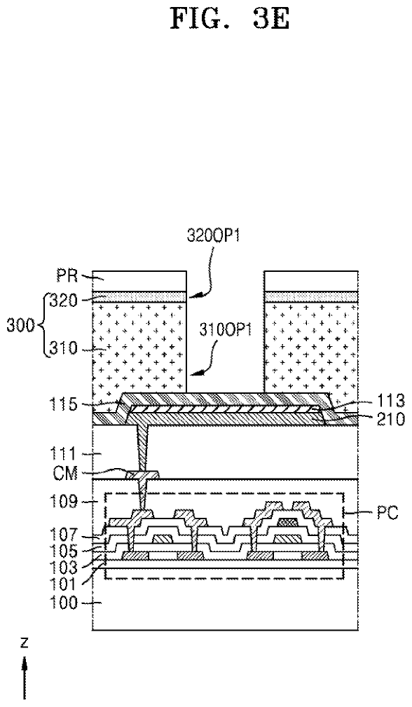

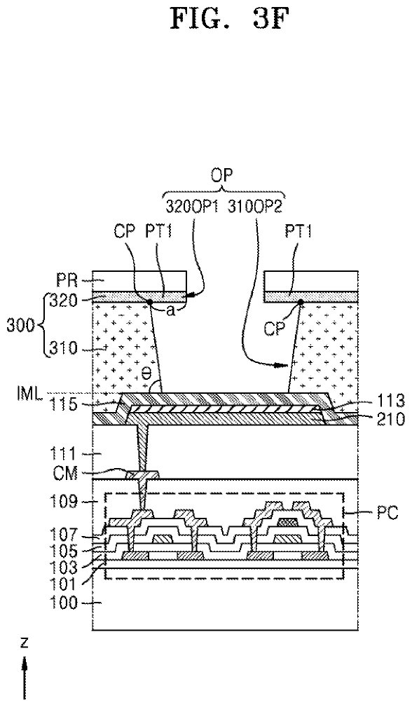

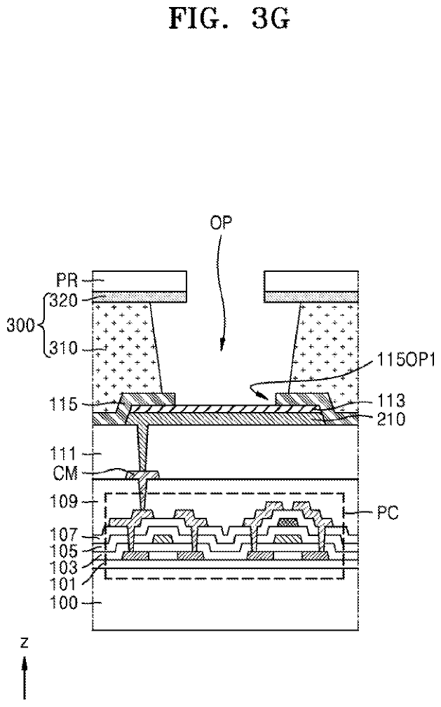

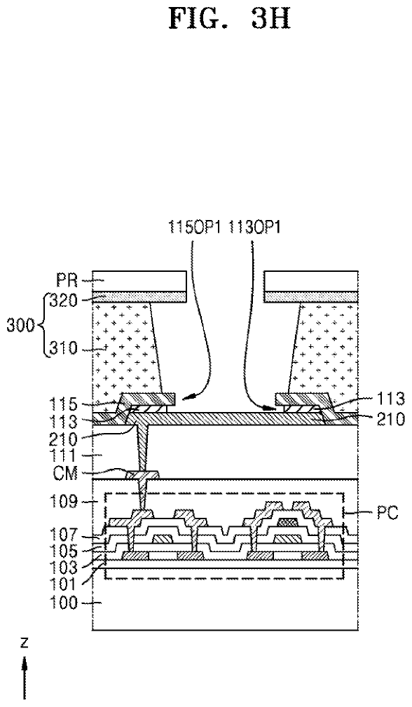

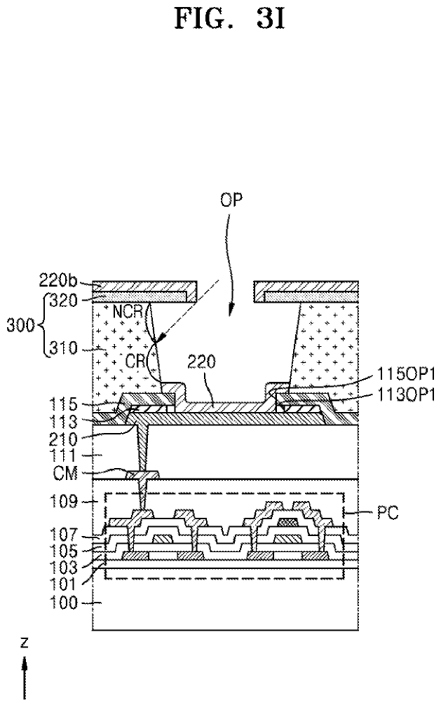

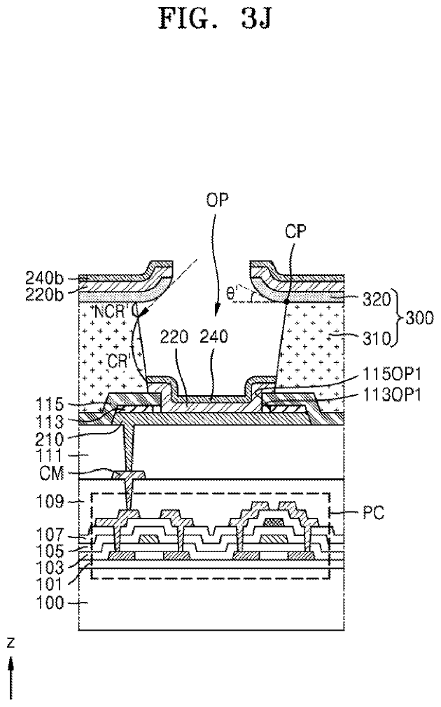

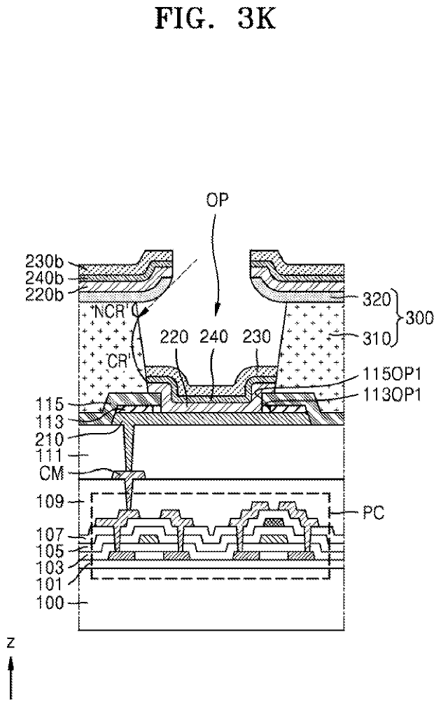

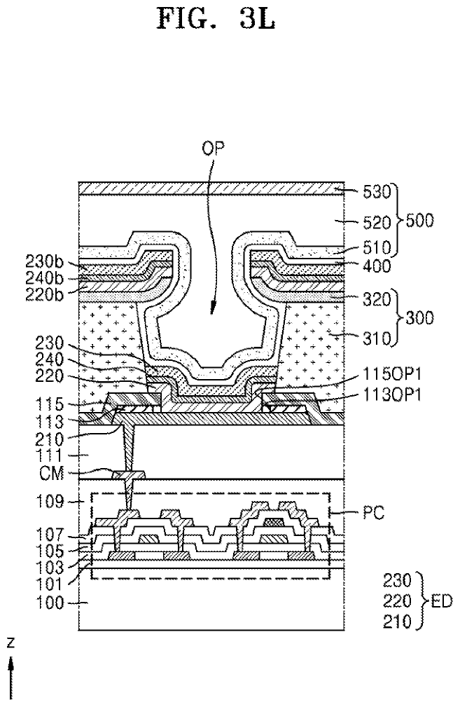

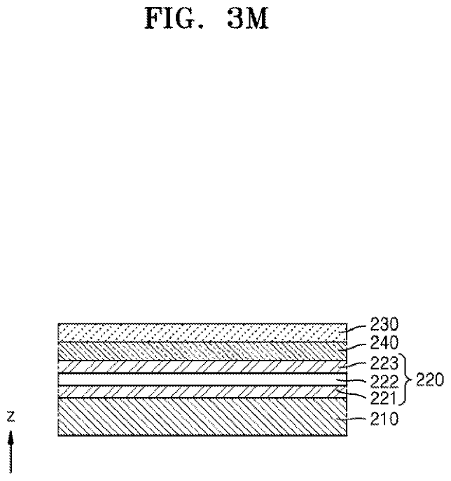

FIGS. 3A to 3L are schematic cross-sectional views of states of a display apparatus according to manufacturing processes, according to an embodiment, and FIG. 3K is a schematic cross-sectional view of a stack structure of a light-emitting diode, according to an embodiment.

Referring to FIG. 3A, the sub-pixel circuit PC may be formed on the substrate 100. The substrate 100 may include a glass material or polymer resin. The substrate 100 may have a structure in which a base layer including polymer resin and an inorganic barrier layer may be sequentially stacked each other. The polymer resin may be polyethersulphone (PES), polyacrylate (PAR), polyetherimide (PEI), polyethyelenene napthalate (PEN), polyethyeleneterepthalate (PET), polyphenylene sulfide (PPS), polyarylate polyimide (PI), polycarbonate, cellulose triacetate (TAC), or cellulose acetate propionate (CAP).

A buffer layer 101 may be disposed on the upper surface of the substrate 100. The buffer layer 101 may prevent impurities from penetrating a semiconductor layer of a transistor. The buffer layer 101 may include inorganic insulating materials, such as silicon nitride, silicon oxynitride, and silicon oxide, and may be a layer or layers including the inorganic insulating materials.

The sub-pixel circuit PC may be disposed above the buffer layer 101. As described above with reference to FIG. 2A or 2B, the sub-pixel circuit PC may include transistors and a storage capacitor. In an embodiment, FIG. 3A shows the first transistor T1, the sixth transistor T6, and the storage capacitor Cst of the sub-pixel circuit PC.

The first transistor T1 may include a first semiconductor layer A1 disposed above the buffer layer 101 and a first gate electrode G1 overlapping a channel area of the first semiconductor layer A1. The first semiconductor layer A1 may include a silicon semiconductor material, for example, polysilicon. The first semiconductor layer A1 may include the channel area and a first area and a second area arranged on both sides of the channel area. The first area and the second area may each be an area including impurities with higher concentration than that of the channel area, and any one of the first area and the second area may be a source area, and the other thereof may be a drain area.

The sixth transistor T6 may include a sixth semiconductor layer A6 disposed above the buffer layer 101 and a sixth gate electrode G6 overlapping a channel area of the sixth semiconductor layer A6. The sixth semiconductor layer A6 may include a silicon semiconductor material, for example, polysilicon. The sixth semiconductor layer A6 may include the channel area and a first area and a second area arranged on both sides of the channel area. The first area and the second area may each be an area including impurities with higher concentration than that of the channel area, and any one of the first area and the second area may be a source area, and the other thereof may be a drain area.

The first gate electrode G1 and the sixth gate electrode G6 may each include a conductive material including molybdenum (Mo), aluminum (Al), copper (Cu), titanium (Ti), or the like and may have a single-layer structure or a multilayered structure including the above material. A first gate insulating layer 103 may be disposed under (or below) the first gate electrode G1 and the sixth gate electrode G6 to electrically insulate the first semiconductor layer A1 from the sixth semiconductor layer A6. The first gate insulating layer 103 may include inorganic insulating materials, such as silicon nitride, silicon oxynitride, and silicon oxide, and may be a layer or layers including the inorganic insulating materials.

The storage capacitor Cst may include the lower electrode CE1 and the upper electrode CE2 which overlap each other. In an embodiment, the lower electrode CE1 of the storage capacitor Cst may include the first gate electrode G1. In other words, the first gate electrode GE1 may include the lower electrode CE1 of the storage capacitor Cst. For example, the first gate electrode G1 may be integral with the lower electrode CE1 of the storage capacitor Cst.

A first interlayer insulating layer 105 may be arranged between the lower electrode CE1 and the upper electrode CE2 of the storage capacitor Cst. The first interlayer insulating layer 105 may include an inorganic insulating material, such as silicon oxide, silicon nitride, or silicon oxynitride, and may have a single-layer structure or a multilayered structure including the inorganic insulating material.

The upper electrode CE2 of the storage capacitor Cst may include low-resistance conductive materials, such as Mo, Al, Cu, and/or Ti, and may have a single-layer structure or a multilayered structure including the above materials.

A second interlayer insulating layer 107 may be disposed above the storage capacitor Cst. The second interlayer insulating layer 107 may include an inorganic insulating material, such as silicon oxide, silicon nitride, or silicon oxynitride, and may have a single-layer structure or a multilayered structure including the inorganic insulating material.

The source electrode S1 and/or the drain electrode D1 electrically connected to the first semiconductor layer A1 of the first transistor T1 may be disposed above the second interlayer insulating layer 107. The source electrode S6 and/or the drain electrode D6 electrically connected to the sixth semiconductor layer A6 of the sixth transistor T6 may be disposed above the second interlayer insulating layer 107. The source electrodes S1 and S6 and/or the drain electrodes D1 and D6 may each include Al, Cu, and/or Ti and may each be a layer or layers including the above material.

The first organic insulating layer 109 may be disposed above the sub-pixel circuit PC. The first organic insulating layer 109 may include an organic insulating material, such as acryl, benzocyclobutene (BCB), PI, or hexamethyldisiloxane (HMDSO).

A contact metal CM may be disposed above the first organic insulating layer 109. The contact metal CM may include Al, Cu, and/or Ti and may be a layer or layers including the above material.

A second organic insulating layer 111 may be arranged between the contact metal CM and a sub-pixel electrode 210. The second organic insulating layer 111 may include an organic insulating material, such as acryl, BCB, PI, or HMDSO. According to the embodiment described with reference to FIG. 3A, the sub-pixel circuit PC is electrically connected to the sub-pixel electrode 210 through the contact metal CM, but according to an embodiment, the contact metal CM may be omitted, and an organic insulating layer may be arranged between the sub-pixel circuit PC and the sub-pixel electrode 210. By way of example, three or more organic insulating layers may be arranged between the sub-pixel circuit PC and the sub-pixel electrode 210, and the sub-pixel circuit PC may be electrically connected to the sub-pixel electrode 210 through contact metals.

The sub-pixel electrode 210 may be formed on the second organic insulating layer 111. The sub-pixel electrode 210 may be a transparent (or translucent) electrode or may be a reflection electrode. In case that the sub-pixel electrode 210 is a transparent (or translucent) electrode, the sub-pixel electrode 210 may include, for example, indium tin oxide (ITO), indium zinc oxide (IZO), zinc oxide (ZnO), indium oxide (In₂O₃), indium gallium oxide (IGO), or aluminum zinc oxide (AZO). In case that the sub-pixel electrode 210 is a reflection electrode, a reflective layer may include silver (Ag), magnesium (Mg), aluminum (Al), platinum (Pt), palladium (Pd), gold (Au), nickel (Ni), neodymium (Nd), iridium (Ir), chromium (Cr), or a compound thereof, and a layer including ITO, IZO, ZnO, or In₂O₃ may be formed on the reflective layer. In an embodiment, the sub-pixel electrode 210 may have a stack structure in which an ITO layer, an Ag layer, and an ITO layer may be sequentially stacked each other. The sub-pixel electrode 210 may be electrically connected to the contact metal CM through a contact hole in the second organic insulating layer 111.

A protective layer 113 may be formed on the sub-pixel electrode 210. The protective layer 113 may be formed together with the sub-pixel electrode 210. For example, the sub-pixel electrode 210 and the protective layer 113 may be formed using the same mask. The protective layer 113 may prevent the sub-pixel electrode 210 from being damaged by gaseous or liquid materials, or the like which are used during various etching processes or ashing processes included in the manufacturing processes of the display apparatus. The protective layer 113 may include conductive oxide, such as ITO, IZO, indium gallium zinc oxide (IGZO), indium tin zinc oxide (ITZO), ZnO, aluminum doped zinc oxide (AZO), gallium doped zinc oxide (GZO), zinc tin oxide (ZTO), gallium tin oxide (GTO), and fluorine doped tin oxide (FTO).

Referring to FIG. 3B, an insulating layer 115 may be formed on the structure shown in FIG. 3A. The insulating layer 115 may be formed on the entire substrate 100. For example, the insulating layer 115 may overlap the sub-pixel electrode 210 and the protective layer 113, but may be in direct contact with an upper surface of the second organic insulating layer 111, on which the sub-pixel electrode 210 and the protective layer 113 do not exist. The insulating layer 115 may cover a side surface of each of the sub-pixel electrode 210 and the protective layer 113. The insulating layer 115 may include an inorganic insulating material. In case that the insulating layer 115 may include an inorganic insulating material, compared to a case where the insulating layer 115 may include an organic insulating material, degradation in the quality of light-emitting diodes may be prevented or reduced, wherein the degradation may occur due to gases discharged from an insulating layer including an organic insulating material during the manufacture of the display apparatus.

The insulating layer 115 may include an inorganic insulating material, such as silicon oxide, silicon nitride, or silicon oxynitride, and may have a single-layer structure or a multilayered structure including the inorganic insulating material. In an embodiment, the insulating layer 115 may be a double structure including a silicon oxide layer and a silicon nitride layer. The thickness of the silicon oxide layer may be less than that of the silicon nitride layer. In an embodiment, the thickness of the insulating layer 115 may be less than that of the protective layer 113. For example, the thickness of the insulating layer 115 may be about 1000 Å, and the thickness of the protective layer 113 may be about 500 Å, but one or more embodiments are not limited thereto.

Referring to FIG. 3C, a conductive bank layer 300 is formed on the insulating layer 115 shown in FIG. 3B. The conductive bank layer 300 may include a first conductive layer 310 and a second conductive layer 320 on the first conductive layer 310.

The first conductive layer 310 and the second conductive layer 320 may include different metals. For example, the first conductive layer 310 and the second conductive layer 320 may include metals with different etch selectivities. In an embodiment, the first conductive layer 310 may be a layer including Al, and the second conductive layer 320 may be a layer including Ti.

The thickness of the first conductive layer 310 may be greater than that of the second conductive layer 320. In an embodiment, the thickness of the first conductive layer 310 may be about five times as large as the thickness of the second conductive layer 320. In an embodiment, the thickness of the first conductive layer 310 may be about 6, 7, or 8 times as large as the thickness of the second conductive layer 320. In an embodiment, the thickness of the first conductive layer 310 may be in a range from about 4000 Å to about 8000 Å, and the thickness of the second conductive layer 320 may be in a range from about 500 Å to about 800 Å. The thickness of the first conductive layer 310 may be about 4, 5, or 6 times as large as the thickness of the insulating layer 115.

Referring to FIG. 3D, photoresist PR is formed on the conductive bank layer 300. The photoresist PR may include an opening overlapping the sub-pixel electrode 210 and the protective layer 113. Through the opening in the photoresist PR, a portion of an upper surface of the conductive bank layer 300 may be exposed.

Referring to FIG. 3E, a portion of the conductive bank layer 300, for example, a portion of the second conductive layer 320 and a portion of the first conductive layer 310, may be removed by using the photoresist PR as a mask. For example, through the opening of the photoresist PR, a portion of the second conductive layer 320 and a portion of the first conductive layer 310 may be sequentially removed. A portion of the second conductive layer 320 and a portion of the first conductive layer 310 may be removed through dry etching. During an etching process, the insulating layer 115 and the protective layer 113 may protect the sub-pixel electrode 210 thereunder.

Through the etching process, an opening 320OP1 overlapping the sub-pixel electrode 210 and the protective layer 113 and penetrating a bottom surface of the second conductive layer 320 from an upper surface thereof may be formed in the second conductive layer 320. In the first conductive layer 310, an opening 310OP1 overlapping the sub-pixel electrode 210 and the protective layer 113 and penetrating a bottom surface of the first conductive layer 310 from an upper surface thereof may be formed.

Referring to FIG. 3F, an opening OP having an undercut form may be formed in the conductive bank layer 300 by using the photoresist PR as a mask.

For example, a portion of the first conductive layer 310 may be further etched by using the photoresist PR as the mask, and in the first conductive layer 310, an opening 310OP2 having a greater width than the opening 310OP1 of the first conductive layer 310, which is formed during the above process of FIG. 3E, may be formed. In an embodiment, the opening 310OP2 of the first conductive layer 310 may have a width decreasing downwards. For example, an upper width of the opening 310OP2 of the first conductive layer 310 may be greater than a lower width thereof. In other words, a side surface of the first conductive layer 310 towards the opening 310OP2 may include an inclined surface tapered in a forward direction.

In an embodiment, the opening OP having the undercut shape may be formed in the conductive bank layer 300 through wet etching. For example, the opening 310OP2 of the first conductive layer 310 may be formed through wet etching. Because the first conductive layer 310 and the second conductive layer 320 have metals with different etch selectivities, a portion of the first conductive layer 310 may be removed through wet etching, and the opening 310OP2 of the first conductive layer 310 that has a greater width than the opening 320OP1 of the second conductive layer 320 may be formed. During the etching process of forming the opening 310OP2 of the first conductive layer 310, the insulating layer 115 and the protective layer 113 may protect the sub-pixel electrode 210 thereunder.

Because the opening 310OP2 of the first conductive layer 310 has a great width while overlapping the opening 320OP1 of the second conductive layer 320, the second conductive layer 320 may have a first tip PT1.

A portion of the second conductive layer 320 that defines the opening 320OP1 of the second conductive layer 320 may protrude towards the opening 320OP1 from a first contact point CP, at which the side surface of the first conductive layer 310 facing the opening 310OP2 of the first conductive layer 310 meets the bottom surface of the second conductive layer 320, and may have an undercut structure. A portion of the second conductive layer 320, which further protrudes towards the opening 320OP1, may correspond to the first tip PT1. The length of the first tip PT1, for example, the length (“a”) from the above-described first contact point CP to an edge (or a side surface) of the first tip PT1, may be less than or equal to about 2 μm. In an embodiment, the length of the first tip PT1 of the second conductive layer 320 may be in a range from about 0.3 μm to about 1 μm or from about 0.3 μm to about 0.7 μm.

An inclination angle θ of the side surface of the first conductive layer 310 (for example, an inclination angle of the side surface of the first conductive layer 310 with respect to a virtual line IML that is parallel to the upper surface of the substrate 100) that faces the opening 310OP2 of the first conductive layer 310 and is tapered in a forward direction may be greater than or equal to about 60° and less than or equal to about 90°.

Referring to FIG. 3G, a portion of the insulating layer 115 may be removed by using the photoresist PR as a mask. A portion of the insulating layer 115 may be removed through dry etching. A width of an opening 115OP1 of the insulating layer 115 may be substantially the same as a width of an open portion of the photoresist PR and/or the upper width of the opening OP of the conductive bank layer 300 (for example, the width of the opening 320OP1 of the second conductive layer 320).

For example, the width of the opening 115OP1 of the insulating layer 115 may be less than the lower width of the first conductive layer 310. A lower portion of the side surface of the first conductive layer 310 (for example, a point at which the side surface of the first conductive layer 310 meets the bottom surface thereof) may meet the upper surface of the insulating layer 115.

Referring to FIG. 3H, a portion of the protective layer 113 may be removed by using the photoresist PR as a mask. A portion of the protective layer 113 may be removed through wet etching, and the sub-pixel electrode 210 may be exposed through an opening 113OP1 of the protective layer 113. The width of the opening 113OP1 of the protective layer 113, which is formed as the protective layer 113 is partially removed, may be greater than that of the opening 115OP1 of the insulating layer 115. In other words, an edge (or a side surface) of the protective layer 113, which defines the opening 113OP1 of the protective layer 113, may be disposed under (or below) the insulating layer 115.

The photoresist PR is removed.

Referring to FIG. 3I, an intermediate layer 220 may be formed on the structure of FIG. 3H, from which the photoresist PR is removed, such that the intermediate layer 220 may overlap the sub-pixel electrode 210. The stack structure of the sub-pixel electrode 210, the intermediate layer 220, and an opposite electrode 230 (of FIG. 3K) corresponds to the light-emitting diode ED. In an embodiment, the intermediate layer 220 may be formed through a deposition method, such as a thermal deposition method.

The intermediate layer 220 may include an emission layer 222, as shown in FIG. 3M. The intermediate layer 220 may include a common layer arranged between the sub-pixel electrode 210 and the emission layer 222 and/or between the emission layer 222 and the opposite electrode 230. Hereinafter, the common layer arranged between the sub-pixel electrode 210 and the emission layer 222 is referred to as a first common layer 221, and the common layer arranged between the emission layer 222 and the opposite electrode 230 is referred to as a second common layer 223.

The emission layer 222 may include a high-molecular-weight or low-molecular-weight organic material emitting a given color of light (red, green, or blue). In an embodiment, the emission layer 222 may include an inorganic material or quantum dots.

The first common layer 221 may include a Hole Transport Layer (HTL) and/or a Hole Injection Layer (HIL). The second common layer 223 may include an Electron Transport Layer (ETL) and/or an Electron Injection Layer (EIL). The first common layer 221 and the second common layer 223 may include organic materials.

The intermediate layer 220 may have a single-stack structure including an emission layer or a tandem structure that is a multi-stack structure including emission layers. In case that the intermediate layer 220 has a tandem structure, a charge generation layer CGL may be arranged between stacks.

Referring back to FIG. 3I, the intermediate layer 220 may overlap and be in contact with the sub-pixel electrode 210 through the opening OP of the conductive bank layer 300, the opening 115OP1 of the insulating layer 115, and the opening 113OP1 of the protective layer 113. The width of the emission area of the light-emitting diode ED may be substantially the same as the width of the opening 115OP1 of the insulating layer 115.

Because the intermediate layer 220 is deposited through the opening OP of the conductive bank layer 300 without any mask, a deposition material for forming the intermediate layer 220 may be used to form a dummy intermediate layer 220b on the conductive bank layer 300. The intermediate layer 220 and the dummy intermediate layer 220b may be separated or spaced apart from each other. The intermediate layer 220 and the dummy intermediate layer 220b may include the same material and/or the same number of sub-layers (for example, a first common layer, an emission layer, and a second common layer).

After the deposition of the intermediate layer 220, the opposite electrode 230 may be deposited through the opening OP of the conductive bank layer 300. Like the intermediate layer 220, the opposite electrode 230 may be deposited in a direction perpendicular to the substrate 100 (for example, a z direction) and a direction oblique thereto. For example, the opposite electrode 230 may be deposited in a direction having a given incidence angle with respect to the z direction. An incidence angle, at which the opposite electrode 230 is deposited, may be identical or similar to an incidence angle, at which the intermediate layer 220 is deposited. Thus, in case that the opposite electrode 230 is deposited through the opening OP of the conductive bank layer 300, an outer portion of the opposite electrode 230 may be in contact with the side surface of the first conductive layer 310.

Because the second conductive layer 320 of the conductive bank layer 300 has an cave structure having the first tip PT1 facing the opening OP, there may be an area, in which the intermediate layer 220 and the opposite electrode 230 are not deposited, by the cave structure. For example, as shown in FIG. 3I, the side surfaces of the first conductive layer 310, which faces the opening OP, may include a contactable region CR, in which the opposite electrode 230 may be in contact with the first conductive layer 310, and a non-contactable region NCR, in which the opposite electrode 230 may not be in contact with the first conductive layer 310 by the first tip PT1. Therefore, in case that the opposite electrode 230 (of FIG. 3K) is formed immediately after the intermediate layer 220 is formed, the contactable region CR, in which the opposite electrode 230 may be in contact with the first conductive layer 310, is small, and thus, the electrical connection between the opposite electrode 230 and the first conductive layer 310 may be unstable.

Accordingly, in an embodiment, an auxiliary layer 240b may be additionally arranged to establish a stable connection between the opposite electrode 230 and the first conductive layer 310. In detail, referring to FIG. 3J, the auxiliary layer 240b and a dummy auxiliary layer 240 may be formed on the structure of FIG. 3I to overlap the intermediate layer 220 and the dummy intermediate layer 220b.

Like the intermediate layer 220, because the auxiliary layer 240b and the dummy auxiliary layer 240 are deposited by the opening OP of the conductive bank layer 300 without a separate mask, the dummy auxiliary layer 240 may be deposited in the opening OP of the conductive bank layer 300, and the auxiliary layer 240b may be formed on the conductive bank layer 300. In detail, the auxiliary layer 240b may be formed on the dummy intermediate layer 220b disposed above the conductive bank layer 300, and the dummy auxiliary layer 240 may be formed on the intermediate layer 220 deposited in the opening OP of the conductive bank layer 300. Thus, the auxiliary layer 240b and the dummy auxiliary layer 240 may be separated or spaced apart from each other. The auxiliary layer 240b may include the same material as the dummy auxiliary layer 240. The auxiliary layer 240b and the dummy auxiliary layer 240 may each have a thickness ranging from about 300 Å to about 1000 Å. For example, the auxiliary layer 240b and the dummy auxiliary layer 240 may each have a thickness ranging from about 300 Å to about 600 Å.

In an embodiment, the auxiliary layer 240b and the dummy auxiliary layer 240 may each be a transparent electrode and include a transparent conductive layer. In detail, the auxiliary layer 240b and the dummy auxiliary layer 240 may each include transparent conductive oxide (TCO). In other words, the auxiliary layer 240b and the dummy auxiliary layer 240 may include at least one selected from the group consisting of indium (In), tin (Sn), zinc (Zn), gallium (Ga), and oxygen (O). For example, the auxiliary layer 240b and the dummy auxiliary layer 240 may each include TCO, such as ITO, GZO, and/or IZO, and the above TCO may be amorphous or crystalline.

In an embodiment, the auxiliary layer 240b and the dummy auxiliary layer 240 may each be a semi-transmissive electrode. In detail, the auxiliary layer 240b and the dummy auxiliary layer 240 may have a multilayered structure in which a transparent conductive layer and a semi-transmissive metal layer may be sequentially stacked each other. The transparent conductive layer may include TCO, such as ITO, GZO, and/or IZO. The semi-transmissive metal layer may include a transparent (or translucent) layer including Ag, Mg, Al, Pt, Pd, Au, Ni, Nd, Ir, Cr, lithium (Li), calcium (Ca), or an alloy thereof.

The auxiliary layer 240b and the dummy auxiliary layer 240 may be formed through sputtering. In case that the auxiliary layer 240b and the dummy auxiliary layer 240 are deposited through sputtering, the internal stress of the auxiliary layer 240b and the dummy auxiliary layer 240 may be adjusted according to pressure conditions. In detail, in case that the auxiliary layer 240b is formed through sputtering under a high-pressure condition, the auxiliary layer 240b may have a tensile stress characteristic. For example, tensile stress is applied to the first tip PT1 of the second conductive layer 320 disposed under (or below) the auxiliary layer 240b, and thus, the first tip PT1 may be curved in an upward direction (for example, the z direction). As the first tip PT1 of the second conductive layer 320 is curved, the dummy intermediate layer 220b disposed on the upper surface of the second conductive layer 320 may be partially curved.

In an embodiment, the auxiliary layer 240b and the dummy auxiliary layer 240 may be formed through sputtering under a pressure condition ranging from about 7 mTorr to about 15 mTorr. For example, in case that formed through sputtering under a high-pressure condition ranging from about 7 mTorr to about 10 mTorr, the auxiliary layer 240b may have a tensile stress characteristic. In case that the auxiliary layer 240b is formed at a pressure lower than the above-described pressure condition, the auxiliary layer 240b may have a compressive stress characteristic. For example, in case that the auxiliary layer 240b is formed through sputtering under a pressure condition that is less than 7 mTorr, a compressive stress is applied to the first tip PT1 disposed under (or below) the auxiliary layer 240b, and thus, the first tip PT1 may be curved in a downward direction.

For example, the auxiliary layer 240b is formed through sputtering under a high-pressure condition, and thus, the first tip PT1 may include a curved portion that is curved in the upward direction (for example, the z direction) from the first contact point CP. A height of an end portion of the curved first tip PT1 may be greater than a height of the first contact point CP. For example, a distance from the end portion of the curved first tip PT1 to the substrate 100 may be greater than a distance from the first contact point CP to the substrate 100. In other words, the end portion of the curved first tip PT1 may be located or disposed above a virtual plane on which the first contact point CP is placed. Here, the end portion of the curved first tip PT1 is spaced apart from the virtual plane in the vertical direction (the z direction) away from the substrate 100.

In case that the first tip PT1 may include the curved portion, the first tip PT1 may include a lower surface, which faces the substrate 100 and is convex towards the substrate 100, and an upper surface, which is concave towards the front. An angle formed by the lower surface of the first tip PT1 with the upper surface of the first conductive layer 310 may be in a range from about 10° to about 40°. In detail, the lower surface of the first tip PT1 is curved, and thus, a gradient thereof may gradually change, but an angle formed by a virtual line, which is in contact with a portion of the lower surface of the first tip PT1, and a virtual line, on which the first contact point CP is located or disposed and which is parallel to the substrate 100, may be in the range from about 10° to about 40°. Also, the width of the first tip PT1 that is curved after the auxiliary layer 240b is formed may be less than the width of the first tip PT1 that is not curved before the auxiliary layer 240b is formed.

As the first tip PT1 of the second conductive layer 320 has a substantially curved shape, the above-described contactable region CR included in the side surface of the first conductive layer 310 may increase, and the non-contactable region NCR may decrease. In detail, the first tip PT1 of the second conductive layer 320 may deposit the opposite electrode 230 without a mask, but a region, in which the opposite electrode 230 is not deposited, is generated by the cave, and thus, the area, in which the opposite electrode 230 may be in contact with the first conductive layer 310, may be relatively small. On the contrary, in case that the first tip PT1 has the curved shape, because the opposite electrode 230 is incident in a direction perpendicular to the substrate 100 or oblique thereto, the area, in which the opposite electrode 230 may be in contact with the first conductive layer 310, may increase, compared to a case where the first tip PT1 is not curved. For example, as the first tip PT1 may include the curved portion, a contactable region CR′, in which the opposite electrode 230 may be in contact with the first conductive layer 310, may increase, and a non-contactable region NCR′ may decrease. As described above, in case that the auxiliary layer 240b is formed through sputtering under a low-pressure condition, the compressive stress may be applied to the first tip PT1 so that the contactable region CR′ may decrease and the non-contactable region NCR′ may increase.

Referring to FIG. 3K, the opposite electrode 230 may be formed on the stricture of FIG. 3J, on which the auxiliary layer 240b is formed, to overlap the intermediate layer 220. The opposite electrode 230 may overlap and be in contact with the intermediate layer 220 through the opening OP of the conductive bank layer 300, the opening 115OP1 of the insulating layer 115, and the opening 113OP1 of the protective layer 113. Like the intermediate layer 220, because the opposite electrode 230 is deposited without a separate mask, a deposition material for forming the opposite electrode 230 may be used to form a dummy opposite electrode 230b on the conductive bank layer 300. The opposite electrode 230 and the dummy opposite electrode 230b may be separated and spaced apart from each other and may include the same material. As the first tip PT1 of the second conductive layer 320 is curved, the dummy opposite electrode 230b disposed on the upper surface of the second conductive layer 320 may be partially curved.

The opposite electrode 230 may include a conductive material having a low work function. In an embodiment, the opposite electrode 230 may include a semi-transmissive electrode. For example, the opposite electrode 230 may include a transparent (or translucent) layer including Yb, Cu, Ag, Mg, Al, Pt, Pd, Au, Ni, Nd, Ir, Cr, Li, Ca, Mo, or an alloy thereof. By way of example, the opposite electrode 230 may further include a transparent conductive layer including ITO, IZO, ZnO, or In₂O₃ on the transparent (or translucent) layer including the above material.

In an embodiment, like the intermediate layer 220, the opposite electrode 230 may be formed through an evaporation process. For example, the opposite electrode 230 may be deposited on the substrate 100 in a chamber by thermally evaporating a material for forming the opposite electrode 230.

In an embodiment, like the auxiliary layer 240b, the opposite electrode 230 may be formed through sputtering. Because the opposite electrode 230 does not need to have a tensile stress characteristic, the opposite electrode 230 may be formed through sputtering under the low-pressure condition. For example, the opposite electrode 230 may be formed under a pressure condition, which is lower than the pressure condition of the sputtering process during which the auxiliary layer 240b is formed. For example, the opposite electrode 230 may be formed through sputtering under the pressure condition ranging from about 3 mTorr to about 7 mTorr.

For example, because the opposite electrode 230 may be deposited in the direction perpendicular or oblique to the substrate 100 through evaporation or sputtering, the edge or the outer portion (or the peripheral portion) of the opposite electrode 230 may extend by passing through the edge or the outer portion of the dummy auxiliary layer 240 and may be in direct contact with the side surface of the first conductive layer 310. The first conductive layer 310 may be electrically connected to the opposite electrode 230. By way of example, because the contactable region CR of the first conductive layer 310 increases as the first tip PT1 of the second conductive layer 320 is curved, the area, in which the opposite electrode 230 may be in contact with the first conductive layer 310, may be sufficiently secured. Accordingly, the electrical connection between the opposite electrode 230 and the first conductive layer 310 may be stable. In the specification, the term “the outer portion (or the peripheral portion) of the opposite electrode 230” may refer to “the portion of the opposite electrode 230 that may include the edge of the opposite electrode 230.”

Referring to FIG. 3L, a capping layer 400 and an encapsulation layer 500 are formed on the structure of FIG. 3K.

The capping layer 400 may improve the external emission efficiency of the light-emitting diode ED, according to the principle of constructive interference. The capping layer 400 may include an organic capping layer including an organic material, an inorganic capping layer including an inorganic material, and a compound capping layer including an organic material and an inorganic material. The capping layer 400 may continuously cover the upper surface of the dummy opposite electrode 230b, the side surface of the conductive bank layer 300, and the upper surface of the opposite electrode 230. In an embodiment, however, the capping layer 400 may be omitted.

The encapsulation layer 500 may include at least one inorganic encapsulation layer and at least one organic encapsulation layer. In an embodiment, FIG. 3I shows that the encapsulation layer 500 may include a first inorganic encapsulation layer 510, an organic encapsulation layer 520 disposed above the first inorganic encapsulation layer 510, and a second inorganic encapsulation layer 530 disposed above the organic encapsulation layer 520.

The first inorganic encapsulation layer 510 and the second inorganic encapsulation layer 530 may each include one or more inorganic materials selected from among aluminum oxide, titanium oxide, tantalum oxide, hafnium oxide, zinc oxide, silicon oxide, silicon nitride, and silicon oxynitride, and may each be deposited through CVD. The first inorganic encapsulation layer 510 and the second inorganic encapsulation layer 530 may each be a layer or layers including the above materials. The organic encapsulation layer 520 may include a polymer-based material. The polymer-based material may include acrylic resin, epoxy-based resin, PI, polyethylene, and the like within the spirit and the scope of the disclosure. In an embodiment, the organic encapsulation layer 520 may include acrylate.

Like the capping layer 400, the first inorganic encapsulation layer 510 with a relatively great step coverage may cover at least a portion of the inner side surface of the opening OP of the conductive bank layer 300 having the undercut structure. In an embodiment, the first inorganic encapsulation layer 510 may be continuously formed to overlap (or cover) the upper surface and the side surface of the dummy opposite electrode 230b, the side surface of the auxiliary layer 240b, the side surface of the dummy intermediate layer 220b, the side surface and the bottom surface of the second conductive layer 320, the side surface of the first conductive layer 310, and the upper surface of the opposite electrode 230.

The organic encapsulation layer 520 may be disposed above the first inorganic encapsulation layer 510 and fill at least a portion of the opening OP of the conductive bank layer 300. The second inorganic encapsulation layer 530 may be disposed above the organic encapsulation layer 520.

In the embodiment shown in FIGS. 3A to 3I, the conductive bank layer 300 may include the first conductive layer 310 and the second conductive layer 320 disposed above the first conductive layer 310, but one or more embodiments are not limited thereto. In an embodiment, the conductive bank layer 300 may include the first conductive layer 310, the second conductive layer 320 disposed above the first conductive layer 310, and a third conductive layer disposed under (or below) the first conductive layer 310, but the third conductive layer may include the same material as or a different material from the first conductive layer.

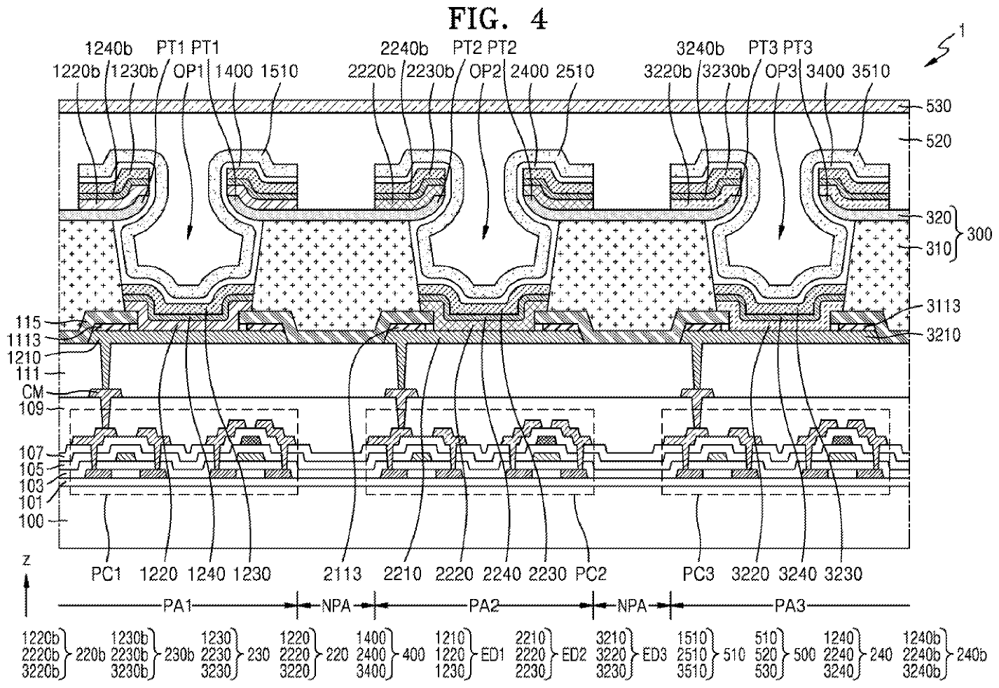

FIG. 4 is a schematic cross-sectional view of a display apparatus according to an embodiment.

Referring to FIG. 4, the display apparatus 1 may include a first sub-pixel area PA1 to a third sub-pixel area PA3 and a non-sub-pixel area NPA between neighboring sub-pixel areas. A planar shape of the display apparatus 1 may be substantially the same as the planar shape of the substrate 100. Therefore, the description that the display apparatus 1 may include the first to third sub-pixel areas PA1 to PA3 and the non-sub-pixel area NPA may indicate that the substrate 100 may include the first to third sub-pixel areas PA1 to PA3 and the non-sub-pixel area NPA.

A first light-emitting diode ED1 to a third light-emitting diode ED3 may be disposed above the substrate 100. The first light-emitting diode ED1 to the third light-emitting diode ED3 may be arranged in the first sub-pixel area PA1 to the third sub-pixel area PA3, respectively.

A first sub-pixel circuit PC1 to a third sub-pixel circuit PC3 may be respectively arranged between the substrate 100 and the first light-emitting diode ED1 to the third light-emitting diode ED3. The first sub-pixel circuit PC1 to the third sub-pixel circuit PC3 may include the transistors and the storage capacitor described above with reference to FIG. 2A or 2B. In an embodiment, FIG. 4 shows that the first sub-pixel circuit PC1 to the third sub-pixel circuit PC3 have the same structure as the sub-pixel circuit (PC of FIG. 3A) described above with reference to FIG. 3A, and the detailed structure is the same as that described above.

The first light-emitting diode ED1 to the third light-emitting diode ED3 respectively electrically connected to the first sub-pixel circuit PC1 to the third sub-pixel circuit PC3 may each have a stack structure including a sub-pixel electrode, an intermediate layer, and an opposite electrode.

For example, the first light-emitting diode ED1 may include a first sub-pixel electrode 1210, a first intermediate layer 1220, and a first opposite electrode 1230. The first sub-pixel electrode 1210 may be electrically connected to the first sub-pixel circuit PC1. The second light-emitting diode ED2 may include a second sub-pixel electrode 2210, a second intermediate layer 2220, and a second opposite electrode 2230. The second sub-pixel electrode 2210 may be electrically connected to the second sub-pixel circuit PC2. The third light-emitting diode ED3 may include a third sub-pixel electrode 3210, a third intermediate layer 3220, and a third opposite electrode 3230. The third sub-pixel electrode 3210 may be electrically connected to the third sub-pixel circuit PC3.

Each of the first intermediate layer 1220, the second intermediate layer 2220, and the third intermediate layer 3220 may include an emission layer and a first common layer and/or a second common layer as described above with reference to FIG. 3M, and the detailed structure and materials thereof are the same as those described above. The emission layer of the first intermediate layer 1220, the emission layer of the second intermediate layer 2220, and the emission layer of the third intermediate layer 3220 may emit different colors of light.

The first opposite electrode 1230, the second opposite electrode 2230, and the third opposite electrode 3230 may be disposed above the first intermediate layer 1220, the second intermediate layer 2220, and the third intermediate layer 3220, respectively. The first opposite electrode 1230, the second opposite electrode 2230, and the third opposite electrode 3230 may include the same material.

As described above, a dummy auxiliary layer may be arranged between the intermediate layer and the opposite electrode. In detail, a first dummy auxiliary layer 1240 may be arranged between the first intermediate layer 1220 and the first opposite electrode 1230, a second dummy auxiliary layer 2240 may be arranged between the second intermediate layer 2220 and the second opposite electrode 2230, and a third dummy auxiliary layer 3240 may be arranged between the third intermediate layer 3220 and the third opposite electrode 3230. The detailed structures and materials of the first dummy auxiliary layer 1240 to the third dummy auxiliary layer 3240 are the same as those described above with reference to FIG. 3J.

Each of the first sub-pixel electrode 1210, the second sub-pixel electrode 2210, and the third sub-pixel electrode 3210 may include an inner portion and an outer portion surrounding the inner portion. In the specification, “an outer portion (or a peripheral portion) of a sub-pixel electrode” may refer to “a portion of the sub-pixel electrode including an edge of the sub-pixel electrode,” and “an inner portion of a sub-pixel electrode” may refer to another portion of the sub-pixel electrode which is surrounded by the above outer portion (or the above peripheral portion).

The first intermediate layer 1220 may overlap and be in contact with the inner portion of the first sub-pixel electrode 1210, and the first dummy auxiliary layer 1240 and the first opposite electrode 1230 may sequentially overlap the first intermediate layer 1220. The insulating layer 115 may be disposed above the outer portion of the first sub-pixel electrode 1210. The insulating layer 115 may overlap the outer portion of the first sub-pixel electrode 1210 and extend onto the second organic insulating layer 111 to cover the side surface of the first sub-pixel electrode 1210. A first protective layer 1113 may be arranged between the insulating layer 115 and the outer portion of the first sub-pixel electrode 1210. The insulating layer 115 and the first protective layer 113 are respectively disposed on the outer portion of the first sub-pixel electrode 1210 and do not exist on the inner portion of the first sub-pixel electrode 1210. In other words, the insulating layer 115 and the first protective layer 1113 may each include an opening overlapping the inner portion of the first sub-pixel electrode 1210.

Similarly, the second intermediate layer 2220 may overlap and be in contact with the inner portion of the second sub-pixel electrode 2210, and the second dummy auxiliary layer 2240 and the second opposite electrode 2230 may sequentially overlap the second intermediate layer 2220. The insulating layer 115 may overlap the outer portion of the second sub-pixel electrode 2210. The third intermediate layer 3220 may overlap and be in contact with the inner portion of the third sub-pixel electrode 3210, and the third dummy auxiliary layer 3240 and the third opposite electrode 3230 may sequentially overlap the third intermediate layer 3220. The insulating layer 115 may overlap the outer portion of the third sub-pixel electrode 3210. The insulating layer 115 may overlap the outer portion of each of the second sub-pixel electrode 2210 and the third sub-pixel electrode 3210 and extend onto the second organic insulating layer 111 to cover the side surface of each of the second sub-pixel electrode 2210 and the third sub-pixel electrode 3210. The second protective layer 2113 may be arranged between the insulating layer 115 and the outer portion of the second sub-pixel electrode 2210, and the third protective layer 3113 may be arranged between the insulating layer 115 and the outer portion of the third sub-pixel electrode 3210.

The conductive bank layer 300 may include a first opening OP1 to a third opening OP3 respectively overlapping the first sub-pixel electrode 1210 to the third sub-pixel electrode 3210. Each of the first opening OP1 to the third opening OP3 of the conductive bank layer 300 of FIG. 4 has the same structure as the opening (OP of FIG. 3F) described above with reference to FIG. 3F.

For example, each of the first opening OP1 to the third opening OP3 may penetrate the bottom surface of the conductive bank layer 300 from the upper surface thereof and may have an undercut cross-sectional shape. The side surface of the first conductive layer 310 which faces a corresponding opening among the first opening OP1 to the third opening OP3 of the conductive bank layer 300 may have a shape tapered in a forward direction and an inclination angle that is equal to or greater than about 60° and less than or equal to about 90°. For example, the second conductive layer 320 of the conductive bank layer 300 may include the first tip PT1 extending towards the first opening OP1, a second tip PT2 extending towards the second opening OP2, and a third tip PT3 extending towards the third opening OP3.

In the display apparatus 1 according to an embodiment, by the structure of the conductive bank layer 300 including the first opening OP1 to the third opening OP3 each having an undercut structure, the first intermediate layer 1220 to the third intermediate layer 3220 and the first opposite electrode 1230 to the third opposite electrode 3230 may be deposited without using a separate mask in case that the first intermediate layer 1220 to the third intermediate layer 3220 and the first opposite electrode 1230 to the third opposite electrode 3230 are formed. Therefore, the damage to the display apparatus 1 by the mask may be prevented.

Because a material for forming an intermediate layer and a material for forming an opposite electrode are deposited without using a mask, the material for forming an intermediate layer and the material for forming an opposite electrode may be deposited not only in a corresponding opening among the first opening OP1 to the third opening OP3 but also on the conductive bank layer 300. At least one dummy intermediate layer and at least one dummy opposite electrode may be disposed on the conductive bank layer 300. At least one dummy intermediate layer may be separated and spaced apart from the first intermediate layer 1220 to the third intermediate layer 3220 respectively arranged in the first opening OP1 to the third opening OP3. At least one dummy opposite electrode may be separated and spaced apart from the first opposite electrode 1230 to the third opposite electrode 3230 respectively arranged in the first opening OP1 to the third opening OP3.

As shown in FIG. 4, the dummy intermediate layer may include a first dummy intermediate layer 1220b arranged in the first sub-pixel area PA1, a second dummy intermediate layer 2220b arranged in the second sub-pixel area PA2, and a third dummy intermediate layer 3220b arranged in the third sub-pixel area PA3. The dummy opposite electrode 230b may include a first dummy opposite electrode 1230b arranged in the first sub-pixel area PA1, a second dummy opposite electrode 2230b arranged in the second sub-pixel area PA2, and a third dummy opposite electrode 3230b arranged in the third sub-pixel area PA3. Because the dummy intermediate layer 220b is etched, leaving an area overlapping each sub-pixel area, the first dummy intermediate layer 1220b, the second dummy intermediate layer 2220b, and the third dummy intermediate layer 3220b may be separated and spaced apart from each other on the second conductive layer 320. As described, because the dummy opposite electrode 230b is also etched with the area overlapping each sub-pixel area, the first dummy opposite electrode 1230b, the second dummy opposite electrode 2230b, and the third dummy opposite electrode 3230b may be spaced apart from each other.

Because the dummy intermediate layer 220b is separated from the intermediate layer 220 by the undercut structure of the conductive bank layer 300, the dummy intermediate layer 220b may include the same material as the intermediate layer 220 in each sub-pixel area. For example, the first dummy intermediate layer 1220b may include the same material as the first intermediate layer 1220, the second dummy intermediate layer 2220b may include the same material as the second intermediate layer 2220, and the third dummy intermediate layer 3220b may include the same material as the third intermediate layer 3220.

Because the dummy opposite electrode 230b is separated from the opposite electrode 230 by the undercut structure of the conductive bank layer 300, the dummy opposite electrode 230b may include the same material as the opposite electrode 230 in each sub-pixel area. For example, the first dummy opposite electrode 1230b may include the same material as the first opposite electrode 1230, the second dummy opposite electrode 2230b may include the same material as the second opposite electrode 2230, and the third dummy opposite electrode 3230b may include the same material as the third opposite electrode 3230.

Also, the auxiliary layer 240b may be arranged between each dummy intermediate layer and each dummy opposite electrode. In detail, the auxiliary layer 240b may include a first auxiliary layer 1240b arranged between the first dummy intermediate layer 1220b and the first dummy opposite electrode 1230b, a second auxiliary layer 2240b arranged between the second dummy intermediate layer 2220b and the second dummy opposite electrode 2230b, and a third auxiliary layer 3240b arranged between the third dummy intermediate layer 3220b and the third dummy opposite electrode 3230b.

As described above with reference to FIG. 3J, in case that formed through sputtering under the high-pressure conditions, the auxiliary layer 240b may have a tensile strength characteristic. For example, in case that the first auxiliary layer 1240b to the third auxiliary layer 3240b are formed through sputtering under the high-pressure conditions, tensile stress is applied to the first tip PT1 to the third tip PT3 disposed under (or below) respective auxiliary layers 240b, and thus, the first tip PT1 to the third tip PT3 may be curved in the upward direction (for example, the z direction).

The first opposite electrode 1230 in the first opening OP1 of the conductive bank layer 300, the second opposite electrode 2230 in the second opening OP2 of the conductive bank layer 300, and the third opposite electrode 3230 in the third opening OP3 of the conductive bank layer 300 may be spatially separated or spaced apart from each other. The first opposite electrode 1230, the second opposite electrode 2230, and the third opposite electrode 3230 may be electrically connected and have the same voltage level. For example, each of the first opposite electrode 1230, the second opposite electrode 2230, and the third opposite electrode 3230 may have the same voltage level as the voltage (for example, the common voltage) provided through the auxiliary line (VSL, see FIG. 2A).

For example, each of the first opposite electrode 1230, the second opposite electrode 2230, and the third opposite electrode 3230 may be electrically connected to the auxiliary line (VSL, see FIG. 2A) through the conductive bank layer 300. For example, the outer portion of the first opposite electrode 1230 is electrically connected to (for example, in direct contact with) the side surface of the conductive bank layer 300 (for example, the side surface of the first conductive layer 310) that faces the first opening OP1, and the conductive bank layer 300 is electrically connected to the auxiliary line (VSL, see FIG. 2A) so that the first opposite electrode 1230 may be electrically connected to the auxiliary line (VSL, see FIG. 2A). As described, the outer portion of the second opposite electrode 2230 may be in contact with the side surface of the second conductive layer 320 that faces the second opening OP2, the outer portion of the third opposite electrode 3230 may be in contact with the side surface of the third conductive layer 330 that faces the third opening OP3, and thus, the second opposite electrode 2230 and the third opposite electrode 3230 may be electrically connected to the auxiliary line (VSL, see FIG. 2A) through the conductive bank layer 300.

By way of example, as shown in FIG. 4, in case that the first tip PT1 to the third tip PT3 of the second conductive layer 320 include curved portions that are curved upwards, the contactable region (CR, see FIG. 3J), in which the opposite electrode may be in contact with the side surface of the first conductive layer 310, may increase. For example, because the area, in which the first opposite electrode 1230 may be in direct contact with the first conductive layer 310, increases due to the curved structure of the first tip PT1, the first opposite electrode 1230 may be stably connected to the conductive bank layer 300. As described, because the area, in which each of the second opposite electrode 2230 and the third opposite electrode 3230 may be in direct contact with the first conductive layer 310, increases due to the curved structures of the second tip PT2 and the third tip PT3, the second opposite electrode 2230 and the third opposite electrode 3230 may be stably connected to the conductive bank layer 300. As a result, because the opposite electrodes may stably receive signals according to the stable connection between each opposite electrode and the conductive bank layer 300, high-quality images may be produced.

The capping layer 400 may be disposed above the first light-emitting diode ED1 to the third light-emitting diode ED3. The capping layer 400 may serve to improve the external emission efficiency of the first light-emitting diode ED1 to the third light-emitting diode ED3. The capping layer 400 may continuously cover the upper surface of the dummy opposite electrode, the side surface of the conductive bank layer 300, and the upper surface of the opposite electrode. The capping layer 400 may include a first capping layer 1400 arranged in the first sub-pixel area PA1, a second capping layer 2400 arranged in the second sub-pixel area PA2, and a third capping layer 3400 arranged in the third sub-pixel area PA3. For example, the first capping layer 1400 may overlap the upper surface and the side surface of the first dummy opposite electrode 1230b, the side surface of the first auxiliary layer 1240b, the side surface of the first dummy intermediate layer 1220b, the side surface and the bottom surface of the second conductive layer 320 which correspond to the first tip PT1, the side surface of the first conductive layer 310, and the upper surface of the first opposite electrode 1230. Materials of the capping layer 400 are the same as those described above with reference to FIG. 3J.

The first light-emitting diode ED1 to the third light-emitting diode ED3 may be encapsulated by the encapsulation layer 500. In an embodiment, FIG. 4 shows that the encapsulation layer 500 may include the first inorganic encapsulation layer 510, the organic encapsulation layer 520 disposed above the first inorganic encapsulation layer 510, and the second inorganic encapsulation layer 530 disposed above the organic encapsulation layer 520. Materials of the first inorganic encapsulation layer 510, the organic encapsulation layer 520, and the second inorganic encapsulation layer 530 are the same as those described above with reference to FIG. 3J.

The first inorganic encapsulation layer 510 may cover a structure and/or a layer disposed thereunder. For example, the first inorganic encapsulation layer 510 with a relatively great step coverage may cover an inner structure and/or layer of each of the first opening OP1 to the third opening OP3. The first inorganic encapsulation layer 510 may include a first sub-pixel inorganic encapsulation layer 1510 arranged in the first sub-pixel area PA1, a second sub-pixel inorganic encapsulation layer 2510 arranged in the second sub-pixel area PA2, and a third sub-pixel inorganic encapsulation layer 3510 arranged in the third sub-pixel area PA3. For example, the first sub-pixel inorganic encapsulation layer 1510 may overlap the upper surface and the side surface of the first dummy opposite electrode 1230b, the side surface of the first auxiliary layer 1240b, the side surface of the first dummy intermediate layer 1220b, the side surface and the bottom surface of the second conductive layer 320 which correspond to the first tip PT1, the side surface of the first conductive layer 310, and the upper surface of the first opposite electrode 1230. A portion of the organic encapsulation layer 520 may at least partially fill each of the first opening OP1 to the third opening OP3, and the second inorganic encapsulation layer 530 may be disposed above the organic encapsulation layer 520.

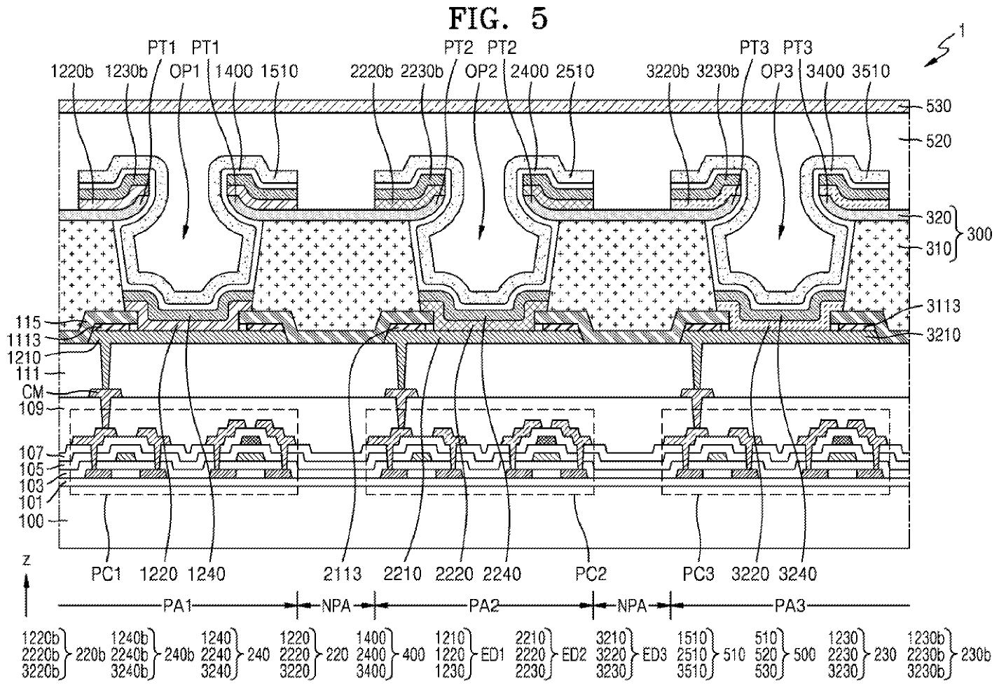

FIG. 5 is a schematic cross-sectional view of a portion of a display apparatus according to an embodiment. Referring to FIG. 5, except for the characteristics regarding the opposite electrode 230 and the dummy opposite electrode 230b, other characteristics are the same as those described above with reference to FIG. 4. The descriptions regarding the same elements shown in FIG. 5 are replaced with the descriptions provided with reference to FIG. 4, and differences therebetween are described hereinafter.

Referring to FIG. 5, the first light-emitting diode ED1 to the third light-emitting diode ED3 may be respectively disposed above the substrate 100. The first light-emitting diode ED1 to the third light-emitting diode ED3 may be arranged in the first sub-pixel area PA1 to the third sub-pixel area PA3, respectively. The first light-emitting diode ED1 to the third light-emitting diode ED3 may each have a stack structure including a sub-pixel electrode, an intermediate layer, and the opposite electrode 230.

For example, the first light-emitting diode ED1 may include the first sub-pixel electrode 1210, the first intermediate layer 1220, and the first opposite electrode 1230, and the first sub-pixel electrode 1210, the first intermediate layer 1220, and the first opposite electrode 1230 may be sequentially stacked each other. As described, the second light-emitting diode ED2 may include a stack structure in which the second sub-pixel electrode 2210, the second intermediate layer 2220, and the second opposite electrode 2230 may be sequentially stacked each other, and the third light-emitting diode ED3 may include a stack structure in which the third sub-pixel electrode 3210, the third intermediate layer 3220, and the third opposite electrode 3230 may be sequentially stacked each other.

Because the intermediate layer and the opposite electrode 230 are formed using the first opening OP1 to the third opening OP3 of the conductive bank layer 300, at least one dummy intermediate layer and at least one dummy opposite electrode 230b may be disposed above the conductive bank layer 300. For example, the first dummy intermediate layer 1220b and the first dummy opposite electrode 1230b may be sequentially stacked each other on the conductive bank layer 300 in the first sub-pixel area PA1, the second dummy intermediate layer 2220b and the second dummy opposite electrode 2230b may be sequentially stacked each other on the conductive bank layer 300 in the second sub-pixel area PA2, and the third dummy intermediate layer 3220b and the third dummy opposite electrode 3230b may be sequentially stacked each other on the conductive bank layer 300 in the third sub-pixel area PA3.

In an embodiment, the opposite electrode 230 and the dummy opposite electrode 230b may each include a transparent conductive layer. In detail, the opposite electrode 230 and the dummy opposite electrode 230b may each include TCO. In other words, the opposite electrode 230 and the dummy opposite electrode 230b may include at least one selected from the group consisting of In, Sn, Zn, Ga, and O. For example, the opposite electrode 230 and the dummy opposite electrode 230b may include TCO, such as ITO, GZO, and/or IZO, and the above TCO may be amorphous or crystalline. The opposite electrode 230 and the dummy opposite electrode 230b may each have a thickness ranging from about 300 Å to about 1000 Å. Because the opposite electrode 230 may include a transparent conductive layer, the first light-emitting diode ED1 to the third light-emitting diode ED3 may form a non-resonant structure.

Also, in the display apparatus 1 of FIG. 5, the opposite electrode 230 and the dummy opposite electrode 230b may be formed through sputtering. As described above, in case that the dummy opposite electrode 230b is formed through sputtering under the high-pressure conditions, the dummy opposite electrode 230b may have a tensile stress characteristic. For example, as the tensile stress is applied to the first tip PT1 of the second conductive layer 320 disposed under (or below) the dummy opposite electrode 230b, the first tip PT1 may be curved in the upward direction (for example, the z direction). As the first tip PT1 of the second conductive layer 320 is curved, the dummy intermediate layer disposed on the upper surface of the second conductive layer 320 may be partially curved. In an embodiment, the opposite electrode 230 and the dummy opposite electrode 230b may be formed through sputtering under a pressure condition ranging from about 7 mTorr to about 15 mTorr. For example, in case that formed through sputtering under a high-pressure condition ranging from about 7 mTorr to about 10 mTorr, the dummy opposite electrode 230b may have a tensile stress characteristic.

For example, in a display apparatus according to an embodiment, unlike the case where the auxiliary layer (240b, see FIG. 4) is formed through sputtering under the high-pressure condition, the dummy opposite electrode 230b is formed through the sputtering under the high-pressure condition, and thus, the first tip PT1 to the third tip PT3 of the second conductive layer 320 may be curved upwards. As described above, in case that the first tip PT1 to the third tip PT3 of the second conductive layer 320 include the curved portions that are curved upwards, the contactable region (CR, see FIG. 3J), in which the opposite electrode 230 may be in contact with the side surface of the first conductive layer 310, may increase. Accordingly, because the area, in which the opposite electrode 230 may be in direct contact with the first conductive layer 310, increases by the curved structures of the first tip PT1 to the third tip PT3, the opposite electrode 230 may be stably connected to the conductive bank layer 300. As a result, in a display apparatus according to an embodiment, because the opposite electrode 230 may stably receive signals according to the stable connection between each opposite electrode 230 and the conductive bank layer 300, high-quality images may be produced.

According to the one or more embodiments, a conductive bank layer including a curved tip is provided for stable contact with an opposite electrode, and thus, high-quality images may be produced. The above effect is an example, and the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display apparatus comprising:
a first sub-pixel electrode disposed on a substrate;
a conductive bank layer comprising a first opening overlapping the first sub-pixel electrode and comprising a first conductive layer and a second conductive layer disposed on the first conductive layer;
a first intermediate layer overlapping the first sub-pixel electrode through the first opening of the conductive bank layer; and
a first opposite electrode overlapping the first intermediate layer through the first opening of the conductive bank layer, wherein
the second conductive layer comprises a first tip that protrudes towards the first opening from a first point, at which a side surface of the first conductive layer meets a bottom surface of the second conductive layer, and
the first tip comprises an upward curved portion with respect to a thickness direction of the substrate.

2. The display apparatus of claim 1, further comprising:
a first dummy intermediate layer disposed on the conductive bank layer, the first dummy intermediate layer and the first intermediate layer comprising a same material; and
a first dummy opposite electrode disposed on the first dummy intermediate layer, the first dummy opposite electrode and the first opposite electrode comprising a same material, wherein
the first intermediate layer is spaced apart from the first dummy intermediate layer, and
the first opposite electrode is spaced apart from the first dummy opposite electrode.

3. The display apparatus of claim 2, further comprising:
an auxiliary layer disposed between the first dummy intermediate layer and the first dummy opposite electrode.

4. The display apparatus of claim 3, further comprising:
a dummy auxiliary layer disposed between the first intermediate layer and the first opposite electrode through the first opening of the conductive bank layer, the dummy auxiliary layer and the auxiliary layer comprising a same material,
wherein the auxiliary layer is spaced apart from the dummy auxiliary layer.

5. The display apparatus of claim 4, wherein the auxiliary layer and the dummy auxiliary layer comprise different materials from the first opposite electrode.

6. The display apparatus of claim 4, wherein a thickness of each of the auxiliary layer and the dummy auxiliary layer is between about 300 Å and about 1000 Å.

7. The display apparatus of claim 3, wherein the auxiliary layer comprises a transparent electrode.

8. The display apparatus of claim 7, wherein the auxiliary layer comprises transparent conductive oxide (TCO).

9. The display apparatus of claim 3, wherein
the auxiliary layer comprises a semi-transmissive electrode, and
the auxiliary layer comprises a transparent conductive layer and a semi-transmissive metal layer.

10. The display apparatus of claim 2, wherein the first opposite electrode and the first dummy opposite electrode comprise a reflection electrode.

11. The display apparatus of claim 10, wherein the first opposite electrode and the first dummy opposite electrode each comprise at least one selected from the group consisting of ytterbium (Yb), copper (Cu), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), and molybdenum (Mo).

12. The display apparatus of claim 2, wherein the first opposite electrode and the first dummy opposite electrode comprise a transparent conductive layer.

13. The display apparatus of claim 12, wherein the first opposite electrode and the first dummy opposite electrode comprise TCO.

14. The display apparatus of claim 1, wherein
the first tip comprises a surface that is convex and another surface that is concave, and
the surface that is convex faces the substrate.

15. The display apparatus of claim 1, wherein an outer portion of the first opposite electrode directly contacts the side surface of the first conductive layer which faces the first opening of the conductive bank layer.

16. A method of manufacturing a display apparatus, the method comprising:
forming a first sub-pixel electrode on a substrate;
forming a conductive bank layer comprising a first opening overlapping the first sub-pixel electrode and comprising a first conductive layer and a second conductive layer disposed on the first conductive layer;
forming a first intermediate layer to overlap the first sub-pixel electrode through the first opening of the conductive bank layer; and
forming a first opposite electrode to overlap the first intermediate layer through the first opening of the conductive bank layer, wherein
the second conductive layer comprises a first tip that protrudes towards the first opening from a first point, at which a side surface of the first conductive layer meets a bottom surface of the second conductive layer, and
the first tip comprises an upward curved portion with respect to a thickness direction of the substrate.

17. The method of claim 16, further comprising:
forming a first dummy intermediate layer disposed on the conductive bank layer, the first dummy intermediate layer and the first intermediate layer comprising a same material; and
forming a first dummy opposite electrode disposed on the first dummy intermediate layer, the first dummy opposite electrode and the first opposite electrode comprising a same material, wherein
the first intermediate layer and the first dummy intermediate layer are formed through a same process and spaced apart from each other, and
the first opposite electrode and the first dummy opposite electrode are formed through a same process and spaced apart from each other.

18. The method of claim 17, further comprising:
forming an auxiliary layer to be disposed between the first dummy intermediate layer and the first dummy opposite electrode after the forming of the first dummy intermediate layer and before the forming of the first dummy opposite electrode.

19. The method of claim 18, wherein the first tip is curved upwards by a tensile stress of the auxiliary layer.

20. The method of claim 18, wherein
the auxiliary layer comprises a transparent electrode, and
the first opposite electrode comprises a semi-transmissive electrode.

21. The method of claim 18, wherein
the auxiliary layer is formed through sputtering, and
the first opposite electrode and the first dummy opposite electrode are formed through evaporation.

22. The method of claim 20, wherein the forming of the auxiliary layer comprises performing sputtering under a pressure ranging from about 7 mTorr to about 15 mTorr.

23. The method of claim 18, wherein
the auxiliary layer is formed through sputtering under a first pressure, and
the first opposite electrode and the first dummy opposite electrode are formed through sputtering under a second pressure that is lower than the first pressure.

24. The method of claim 23, wherein
the first pressure is between about 7 mTorr and about 15 mTorr, and
the second pressure is between about 3 mTorr and about 7 mTorr.

25. The method of claim 17, wherein the first opposite electrode and the first dummy opposite electrode comprise a transparent electrode.

26. The method of claim 25, wherein the first opposite electrode and the first dummy opposite electrode are formed through sputtering under a pressure ranging from about 7 mTorr to about 15 mTorr.

27. The method of claim 25, wherein the first tip is curved upwards by a tensile stress of the first dummy opposite electrode.
